(19) United States
(12) Patent Application Publication
(10) Pub. No.: US 2004/0105230 A1
(43) Pub. Date: Jun. 3, 2004

(54) Case for portable storage peripheral equipment having cable assembly with strain relief

(76) Inventor: Yi-Sheng Lin, Tu-chen (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/331,087

(22) Filed: Dec. 24, 2002

(30) Foreign Application Priority Data
Nov. 29, 2002 (TW) 91219295

(51) Int. Cl. G06F 1/16; H05K 5/00

(52) U.S. Cl. 361/685

(57) ABSTRACT

A case (1) is provided for receiving a portable storage peripheral equipment which generally accomplishes signal transmission with a computer. The case includes a case body having a front wall (16) and defining a receiving space (60) for receiving the portable storage peripheral equipment and a cable assembly (30). The front wall defines an aperture therein. The cable assembly has a cable (31), a cable connector (34) at a free end thereof, and a strain relief (32) opposite to the cable connector. The strain relief has a block portion (322) exposed to the aperture. The block portion defines a recess (323). The cable extends out of the case body from the recess of the block portion and can be rotate towards various directions when needed.

### CROSS-REFERENCE TO RELATED APPLICATION

This patent application is related to a co-pending application of U.S. patent application Ser. No. 29/169,745, filed Oct. 24, 2002, entitled “CASE FOR PORTABLE STORAGE PERIPHERAL”, and contemporaneously filed applications entitled “CASE FOR PORTABLE STORAGE PERIPHERAL EQUIPMENT”, entitled “CASE FOR RECEIVING PORTABLE STORAGE PERIPHERAL EQUIPMENT”, and entitled “CASE FOR PORTABLE STORAGE PERIPHERAL EQUIPEMNT HAVING IMPROVED SHIELDING EFFECT”, all invented by the same inventor, and assigned to the same assignee as the present application.

### BACKGROUND OF THE INVENTION

1. Field of the Invention

The present invention relates to a case for portable storage peripheral equipment, and particularly to a case having a cable assembly with a strain relief structure thereof.

2. Description of Related Art

Following the popularity of the data processing machines, i.e., computers, or serves, information processing with the machine, is increased enormously. Generally, the information is stored in an internal store equipment, such as a hard disk, a floppy disk or a compact disc of the computer. However, such internal stores are not satisfied with requirements of the development that the computer becomes portable and low profile. The external portable storage peripheral equipment is developed and becomes more and more popular.

Generally, the external portable storage peripheral equipment is received in a case. A printed circuit board module (PCB module) is provided in the case with a device connector mounted on the PCB module. The device connector mates with an electrical connector mounted to a front portion of the external portable storage peripheral equipment. The case further comprises a cable assembly electrically connecting with the PCB module and extending outside of the case for mating with a device connector mounted on a mother board of a notebook computer for providing signal transmission. The cable assembly integrally extends out of the case generally with a strain relief over-molded between the cable connector and the cable. The conventional strain relief is cuboid and defines a plurality of cutouts in periphery for providing a strain relief function. Furthermore, the cuboid strain relief has an enough length beyond the case. However, the cable assembly with the conventional cuboid strain relief occupies more external space. Furthermore, in use, the cable may rotate towards various directions. The frequent rotation of the cable may break the strain relief which affects the signal transmission.

Hence, a case for portable storage peripheral equipment is required to overcome the disadvantages of the related art.

### SUMMARY OF THE INVENTION

Accordingly, an object of the present invention is to provide a case for portable storage peripheral equipment with a cable assembly having an improved strain relief structure.

In order to achieve the object set forth, a case in accordance with the present invention comprises a case body having a perimeter and defining a receiving space surrounded by the perimeter for receiving a portable storage peripheral equipment and a cable assembly. The perimeter defines an aperture therein. A cable assembly comprises a cable, a cable connector at a free end thereof, and a strain relief opposite to the cable connector. The strain relief has a cricoid block portion. The block portion defines a recess therein. The cable extends out of the case body from the recess of the block portion.

Other objects, advantages and novel features of the invention will become more apparent from the following detailed description when taken in conjunction with the accompanying drawings.

### BRIEF DESCRIPTION OF THE DRAWINGS

FIG. 1 is an assembled perspective view of a case for portable storage peripheral equipment in accordance with the present invention;

FIG. 2 is an exploded, perspective view of the case for portable storage peripheral equipment of FIG. 1;

FIG. 3 is a bottom perspective view of a top cover of the case for portable storage peripheral equipment of FIG. 1;

FIG. 4 is a top perspective view of a bottom cover of the case for portable storage peripheral equipment of FIG. 1; and

FIG. 5 is a similar view to FIG. 3, but showing the cable assembly assembled on the top cover.

### DETAILED DESCRIPTION OF THE INVENTION

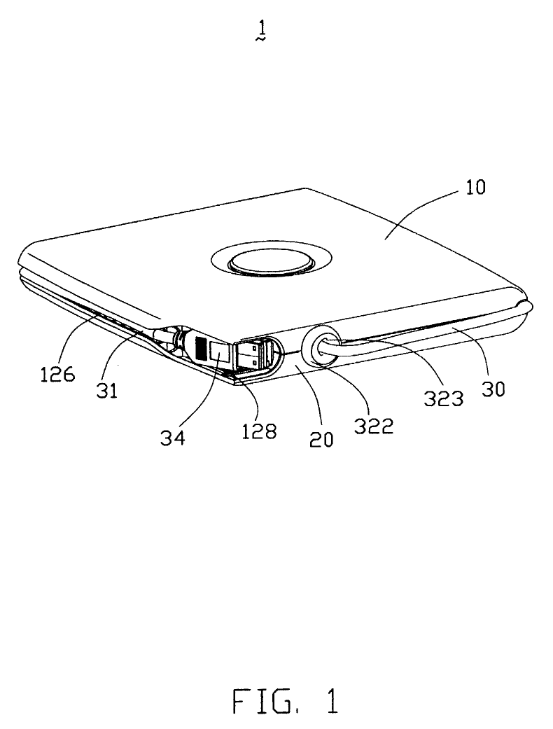

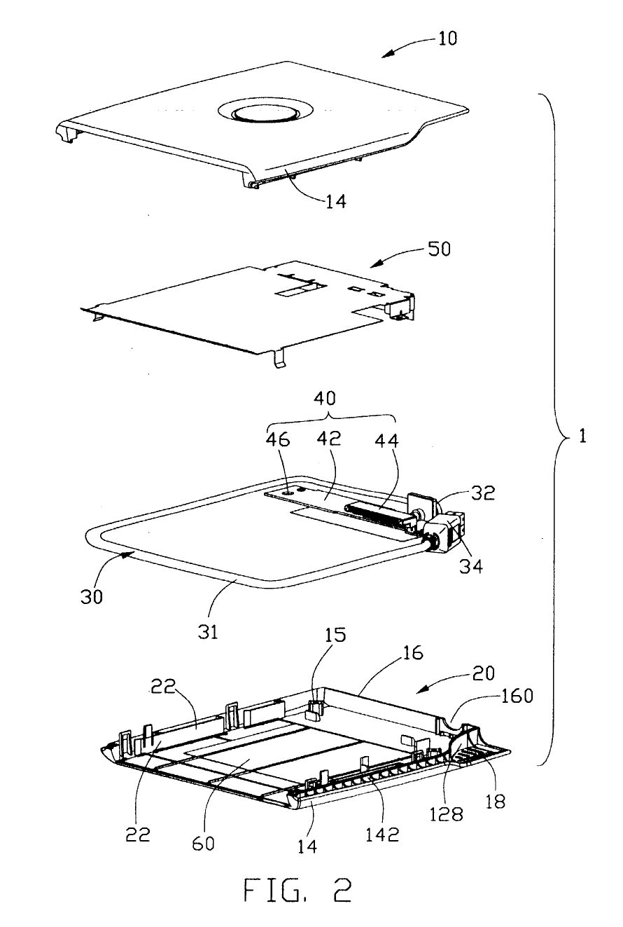

Referring to FIGS. 1-2, a case 1 for portable storage peripheral equipment in accordance with the present invention is generally rectangular in shape. The case 1 comprises a case body consisting of a top cover 10 and a bottom cover 20, a cable assembly 30, a printed circuit board module 40 (PCB module), and a shielding 50. The top cover 10 and the bottom cover 20 are assembled together and a receiving space 60 is thus defined therebetween. The PCB module 40 and the shielding member 50 are assembled in the receiving space 60. A corresponding portable storage peripheral equipment (not shown), i.e. a portable hard disk, a floppy disk or a compact disc, is accommodated in the receiving space 60 for providing a signal transmission with a notebook computer by the PCB module 40 and the cable assembly 30.

Also referring to FIGS. 2-4, the top cover 10 has a similar configuration with the bottom cover 20 and opposite to the top cover 10. Each cove 10, 20 has a flat board 12, a pair of sidewalls 14 respectively extending curvely and outwardly from a pair of sides of the flat board 12, and a front wall 16 extending from a front side of the flat board 12 and a pair of ends of the front wall 16 connecting the pair of sidewalls 14. One sidewall 14 has a transitional part 140 adjacent to the front wall 16. The transitional part 140 deflects towards a center of the flat board 12 relative to the other part of the sidewall 14 and a recess 120 is thus defined by the transitional part 140 and the flat board 12. A pair of cushions 18 is respectively attached on bottom surfaces of the recesses 120 of the top cover 10 and the bottom cover 20.

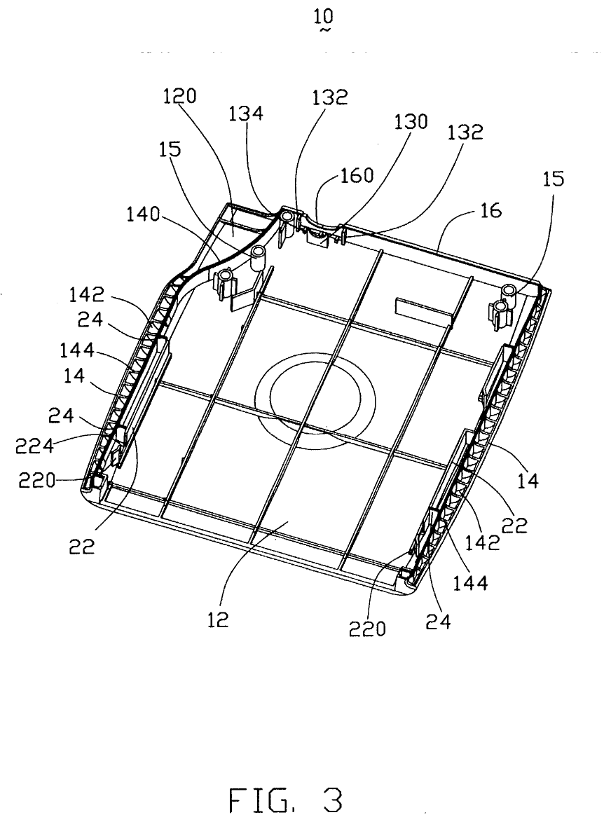

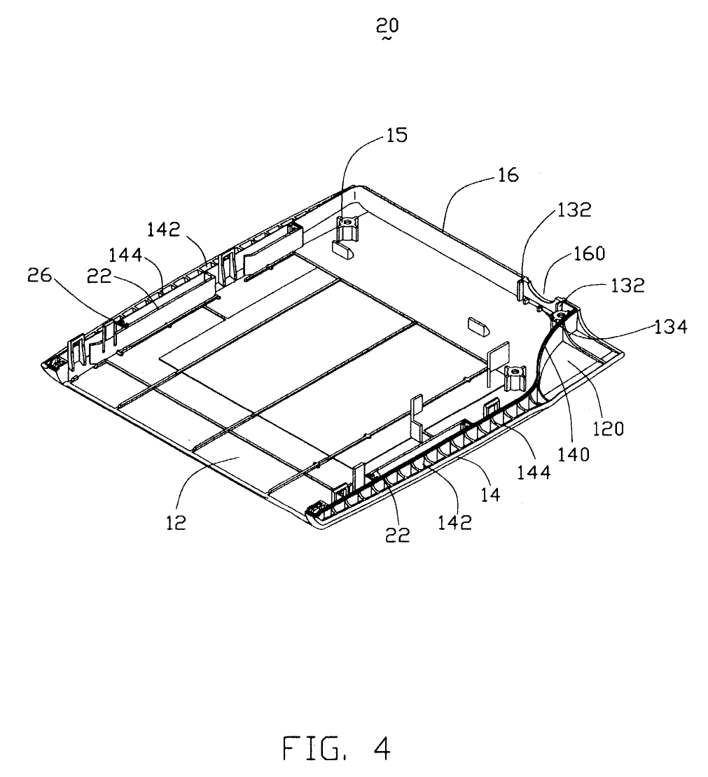

Referring to FIGS. 3-4, each front wall 16 defines a pair of retaining bars 132 protruding into the receiving space 60 and adjacent to a corresponding recess 120. A hemicycle orifice 160 is defined between the pair of retaining bars 132. Each flat board 12 of the top, bottom cover 10, 20 has a plurality of supporting blocks 134 extending upwardly therefrom and locating between the pair of retaining bars 132. The flat board 12 of the top cover 10 forms a supporting bar 130 which defines a cutout (not labeled) aligning with the hemicycle orifice 160. The supporting bar 130 locates away from the front wall 16. The cutout 130 is in an arcuate shape for nicely accommodating the jacket of the cable 31.

Each sidewall 14 of the covers 10, 20 defines a groove 142 therein. A plurality of arcuate ribs 144 protrudes equably into the corresponding groove 142. Each flat board 12 of the top cover 10 and the bottom cover 20 protrudes a plurality of baffles 22 parallel to the sidewall 14 thereof adapted for engaging with corresponding portable storage peripheral equipment. The top cover 10 has a plurality of locking flakes 24 protruding downwardly therefrom, as shown in FIG. 3. The bottom cover 20 defines a corresponding number of locking apertures 26 for snugly receiving the locking flakes 24 of the top cover 10, best shown in FIG. 4.

The PCB module 40 includes a printed circuit board 42 and an electrical connector 44 assembled thereto. The printed circuit board 42 defines a plurality of retaining holes 46 corresponding to posts (not labeled) of the top cover 10 provided for arranging and fastening the PCB module 40 in the receiving space 60 by a plurality of corresponding screws (not shown).

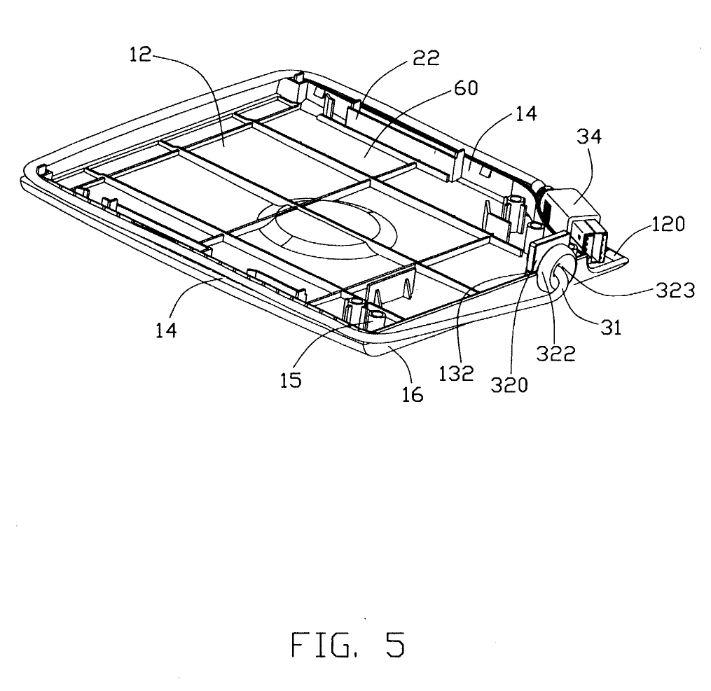

The cable assembly 30 comprises a cable 31 and a cable connector 34 at a free end of the cable 31. Referring to FIG. 2 and FIG. 5, the cable 31 has a strain relief 32 for engaging with the case body. The strain relief 32 is over-molded with and encloses a segment of the cable 31. The strain relief 32 includes a rectangular base 320 and a block portion 322 protruding from the base 320. The block portion 322 is cricoid and has a recess 323 at a center thereof. The recess 323 is in a bulge shape. In alternative embodiments, the recess 323 can be in a other shape, such as a funnel shape. The block portion 322 is snugly assembled to the hemicycle orifice 160 of the front wall 16. The base portion 320 has a dimension larger than that of the block portion 322. The cable 31 is mounted to the PCB 42 with an end thereof opposite to the cable connector 34 soldered on the PCB 42. The cable 31 extends out from the recess 323 of the block portion 322 and the cable connector 34 at the free end thereof is provided for mating with a device connector mounted on a mother board of the notebook computer.

In assembly, the strain relief 32 of the cable assembly 30 fixes to the hemicycle orifice 160. The rectangular base portion 320 is inserted between the pair of retaining bars 132 with a lower edge thereof engaging with corresponding supporting blocks 134. The retaining bars 132 can prevents the base portion 320 of the cable assembly 30 from sliding along left-to-right direction. Furthermore, the base portion 320 locates between the supporting bar 130 and the front wall 16 with a rear surface of the base portion 320 thereof abutting against the supporting bar 130. In other words, the supporting bar 130 and the front wall 16 respectively clip the base portion 320 for preventing the base portion 320 from sliding along front-to-back direction.

The PCB module 40 is assembled in the receiving space 60 adjacent to the front wall 16. The shielding member 50 generally manufactured from metal or other conductive materials is assembled on an inner surface of the flat board 12 of the top cover 10. The locking flakes 24, thereafter, are inserted in corresponding locking apertures 26. The top cover 10 and the bottom cover 20 are thus fastened with each other. The hemicycle orifices 160 of the top cover 10 and the bottom cover 20 inosculate to each other to provide a circular aperture (not labeled). The block portion 322 of the strain relief 32 is nicely retained in the circular aperture. The cable 31 extends out from the center recess of the block portion 322. Further, the grooves 142 of the sidewalls 14 of the top cover 10 and the bottom cover 20 confront to each other and a receiving channel 126 is thus formed by the pair of grooves 142. Similarly, the recesses 120 of the top cover 10 and the bottom cover 20 confront to each other for providing a retaining cavity 128.

Referring to FIG. 5, in use, the portable storage peripheral equipment is inserted into the receiving space 60 with a complementary connector thereof mating with the electrical connector 44 of the PCB module 40 therein. The cable 31 extends out of the case 1 and the cable connector 34 mates with a device connector of the computer. The signal transmission and conversion between the portable storage peripheral equipment and the computer is thus accomplished by the PCB module 40 and the cable assembly 30.

One feature of the present invention over the prior art is that the cable 31 extends out from the recess 323 of the strain relief of the cable 31. The cable 31 can be rotate towards various directions when needed so that a center conductor of the cable 31 is not damaged. Furthermore, the cable 31 extends out from the block portion 322 surrounding the case body and thus does not occupy more external space.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A case comprising:
a case body having a perimeter, the perimeter defining an aperture therein; and
a cable assembly extending out of the case body and comprising a cable, a cable connector at a free end of the cable, and a strain relief on the cable opposite to the cable connector, the strain relief having a block portion assembled to the perimeter and exposed to the aperture, the block portion defining a recess, the cable extending out of the case body from the recess.

2. The case as claimed in claim 1, wherein the block portion is in a cricoid shape.

3. The case as claimed in claim 2, wherein the recess of the block portion is in a bulge shape.

4. The case as claimed in claim 1, wherein the strain relief is over-molded and encloses a segment of the cable adjacent to the case body.

5. The case as claimed in claim 1, wherein the strain relief comprises a base portion, the block portion is integrally molded with the base portion and remained in the case body for preventing the strain relief from sliding away the case body.

6. The case as claimed in claim 5, wherein the base portion of the strain relief has a dimension larger than that of the aperture.

7. The case as claimed in claim 6, wherein the block portion is snugly accommodated into the aperture.

8. The case as claimed in claim 7, wherein the aperture is a circular shape and the periphery of is in a round shape.

9. The case as claimed in claim 5, wherein the perimeter of the case body defines a pair of retaining bars extending inwardly for engaging with the both sides of the base portion of the strain relief.

10. A case for portable storage peripheral equipment comprising:
a case body having a perimeter and defining a receiving space for receiving a portable storage peripheral equipment, the perimeter defining a aperture therein; and
a cable assembly comprising a cable with a strain relief thereof, the strain relief having a block portion extending through out of the aperture, the block portion defining a recess therein, the cable extending out the case body from the recess.

11. The case for portable storage peripheral equipment as claimed in claim 10, wherein the strain relief comprises a base portion, the block portion is integrally molded with the base portion.

12. The case for portable storage peripheral equipment as claimed in claim 11, wherein the case body defines a plurality of supporting blocks protruding into the receiving pace for respectively engaging with the top, lower sides of the base portion of the strain relief.

13. The case for portable storage peripheral equipment as claimed in claim 10, wherein the case body comprises a supporting bar extending into the receiving space and away from the perimeter, the supporting bar defining a cutout aligning with the aperture for accommodating with the jacket of the cable.

14. The case for portable storage peripheral equipment as claimed in claim 10, further comprising a printed circuit board module, the cable electrically connected with the printed circuit board module.

15. A portable storage peripheral equipment comprising:
a flat type box having a rectangular contour defining lengthwise and lateral directions perpendicular to each other, with a less height extending in a vertical direction perpendicular to both said lengthwise and lateral directions;
an through hole formed in a position of a periphery of said rectangular contour of said case and open to an exterior in said lengthwise direction; and
a strain relief of a cable occupying said through hole with an extension line of said cable extending outwardly from said strain relief; wherein
said strain relief is configured with an inwardly conical recess coaxially, along said lengthwise direction, surrounding said extension line so as to have the extension line easily deflected along an oblique extending configuration of said recess toward the periphery and further extending in said lateral direction for receipt within a channel defined in the periphery.
